(19) United States
(12) Patent Application Publication
(10) Pub. No.: US 2013/0298395 A1
(43) Pub. Date: Nov. 14, 2013

(54) METHOD FOR MANUFACTURING FLEXIBLE PRINTED CIRCUIT BOARD

(71) Applicant: CHIH-CHEN LAI, Tu-Cheng (TW)

(72) Inventor: CHIH-CHEN LAI, Tu-Cheng (TW)

(21) Appl. No.: 13/651,633

(22) Filed: Oct. 15, 2012

(30) Foreign Application Priority Data
May 9, 2012 (TW) 101116447

(51) Int. Cl. H05K 3/00

(52) U.S. Cl. 29/829

(57) ABSTRACT

A method for manufacturing a FPCB includes following steps. A support device and an unfinished FPCB are provided. The unfinished FPCB includes a substrate, a conductive trace layer, and a solder mask layer in sequence. The conductive trace layer includes exposed connecting terminals. The unfinished FPCB is divided into an effective region and an unwanted region surrounding the effective region. A blinded groove is formed at the unwanted region. The connecting terminals are located in the effective region. The unfinished FPCB is put on the support device. A heating device is inserted into the blinded groove to heat the substrate and the support device to adhere together and then the heating device is removed. A tin cream layer is dispensed on each connecting terminal. An electronic component is mounted on each tin cream layer. The unfinished FPCB is cut to separate the effective region from the unwanted region.

### BACKGROUND

1. Technical Field

The present disclosure relates to a method for manufacturing a flexible printed circuit board.

2. Description of Related Art

When manufacturing a flexible printed circuit board (FPCB), an unfinished FPCB is carried on a support plate, a tin cream layer is dispensed on the unfinished FPCB, electronic components are mounted on the tin cream layer, then the unfinished FPCB is reflowed to fix the electronic components on the tin cream layer. During the above mentioned processes, the unfinished FPCB may warp. This affects the quality of the FPCB.

Therefore, it is desired to provide a method for manufacturing a FPCB which can overcome the above-mentioned problems.

### BRIEF DESCRIPTION OF THE DRAWINGS

FIGS. 1-8 are schematic views showing successive stages of a method for manufacturing a FPCB according to an exemplary embodiment.

### DETAILED DESCRIPTION

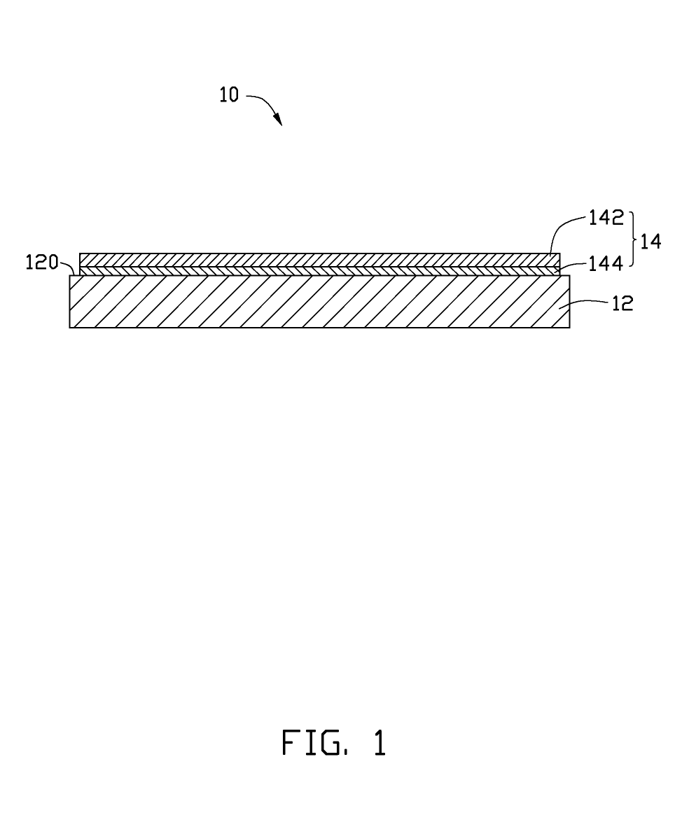

FIGS. 1 to 8 show successive stages of a method for manufacturing a FPCB according to an exemplary embodiment. The method includes following steps S10-S90.

In step 1, as shown in FIG. 1, a support device 10 is provided. The support device 10 includes a support plate 12 and a connecting plate 14 attached to the support plate 12.

The support plate 12 is made of aluminum. A supporting surface 120 of the support plate 12 for supporting the connecting plate 14 is a smooth surface. The connecting plate 14 includes a connecting layer 142 and an attachment layer 144. The attachment layer 144 is sandwiched between the connecting layer 142 and the support surface 120. The connecting layer 142 is made of resin, such as Polyimide, Polyethylene Terephtalate, Polythylene Naphthalate. The attachment layer 144 is made of resin, such as Polyethylene Terephthalate. One surface of the attachment layer 144 is adhered to the connecting layer 142, an opposite surface of the attachment layer 144 is electrostatically adhered to the support surface 120. In other embodiment, the attachment layer 144 can be a double-sided adhesive adhering to the connecting layer 142 and the support plate 12 respectively.

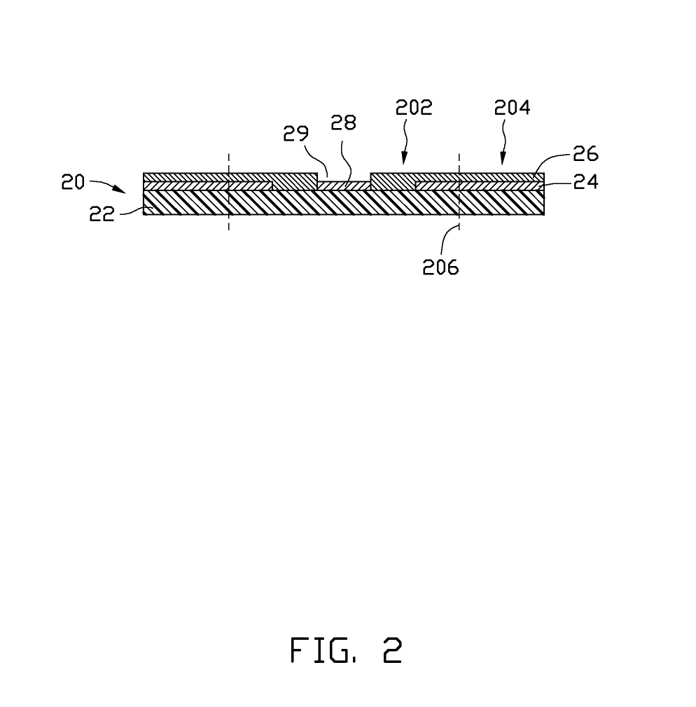

In step 2, as shown in FIG. 2, an unfinished FPCB 20 is provided. The unfinished PFCB 20 includes an insulated substrate 22, a conductive trace layer 24 formed on the substrate 22, and a solder mask layer 26 formed on the conductive trace layer 24. The conductive trace layer 24 includes connecting terminals 28. The solder mask layer 26 defines holes 29 for exposing the connecting terminals 28.

The substrate 22 is made of resin, such as Polyimide, Polyethylene Terephtalate, Polythylene Naphthalate. The material for making the substrate 22 may be the same as that for making the connecting layer 142. The conductive trace layer 24 is made of copper, and is formed on the substrate 22 by a combination image transfer process and etching process. The solder mask layer 26 is formed on the conductive trace layer 24 by a screen printing process. The method for forming the conductive trace layer 24 and the solder mask layer 26 is familiar to one skilled in the art, thus, a detailed description is omitted here.

The unfinished FPCB 20 is divided into an effective region 202 and an unwanted region 204 surrounding the effective region 202. The connecting terminals 28 are located in the effective region 202. The effective region 202 is used to form a FPCB and the unwanted region 204 must be removed from the effective region 202. The unfinished FPCB 20 includes a boundary 206 between the effective region 202 and the unwanted region 204.

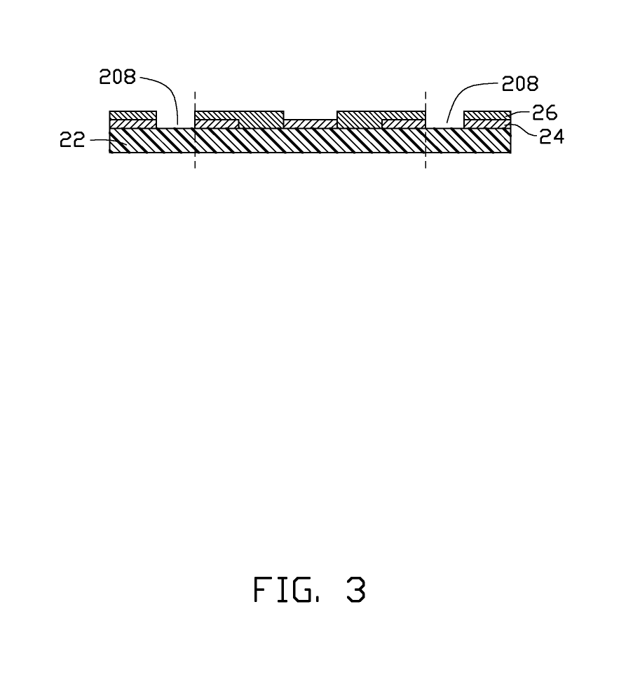

In step 3, as shown in FIG. 3, a blind groove 208 is formed in the unwanted region 204. The blind groove 208 extends through the solder mask layer 26 and the conductive trace layer 24, and terminates at the substrate 22. In this way, the substrate 22 is exposed in the blind groove 208. The blind groove 208 is adjacent to the boundary 206 and surrounding the effective region 202 in this embodiment. The blind groove 208 can be formed by a combination of an image transfer process and an etching process, or can be formed by a laser machining process.

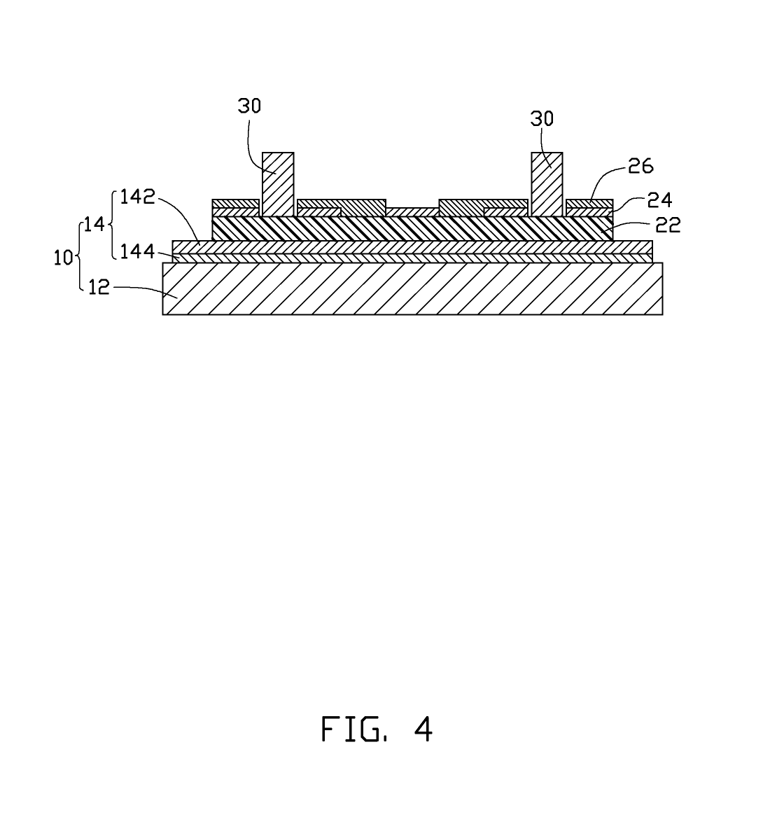

In step 4, as shown in FIG. 4, the unfinished FPCB 20 with the blind groove 208 is put on the support device 10, and the substrate 22 is in contact with the connecting layer 142.

In step 5, a heating device 30 is inserted into the blind groove 208 to press the substrate 22. In this embodiment, the heating device 30 includes a number of heating rods. The temperature of the heating rods 30 is greater than the glass transition temperature of the substrate 22 and the connecting layer 142. At the blind groove 208, the substrate 22 and the connecting layer 142 are melted and adhered to each other. Then the heating rods 30 are removed from the blind groove 208. The substrate 22 and the connecting layer 142 are cooled to solidify the melted portion. In this way, the substrate 22 and the connecting layer 142 are connected to each other at the blind groove 208, and are separated from each other at the effective region 202. In this embodiment, the glass transition temperature of the substrate 22 and the connecting layer 142 is about 260 degrees Celsius. The temperature of the heating rods 30 is about 300 degrees Celsius. The time for which the heating rods 30 heat the substrate 22 is about 0.5 seconds.

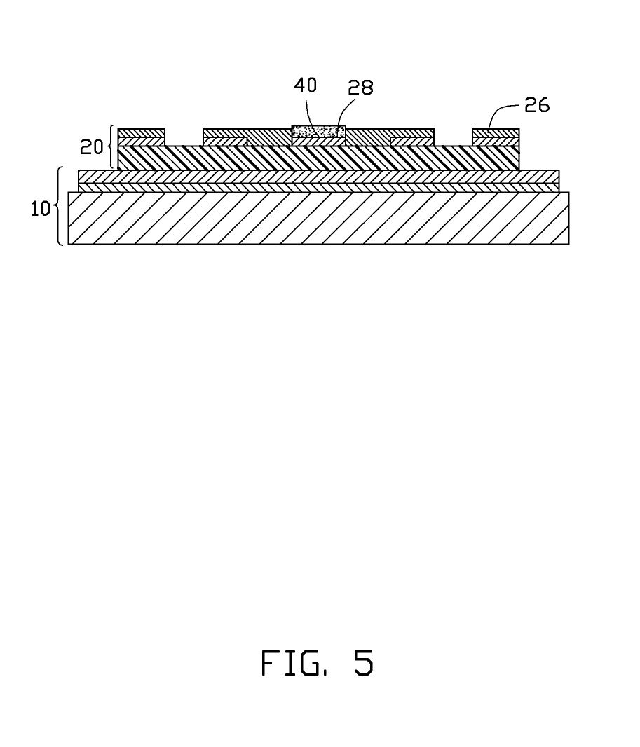

In step 6, referring to FIG. 5, a tin cream layer 40 is formed on each of the connecting terminals 28. When forming the tin cream layer 40, a steel plate (not shown) defining holes, is put above the unfinished FPCB 20. The holes are aligned with the connecting terminals 28, a tin cream is dispensed on the steel plate and a scraper (not shown) is used to scrape the tin cream to the connecting terminals 28 to form the tin cream layer 40.

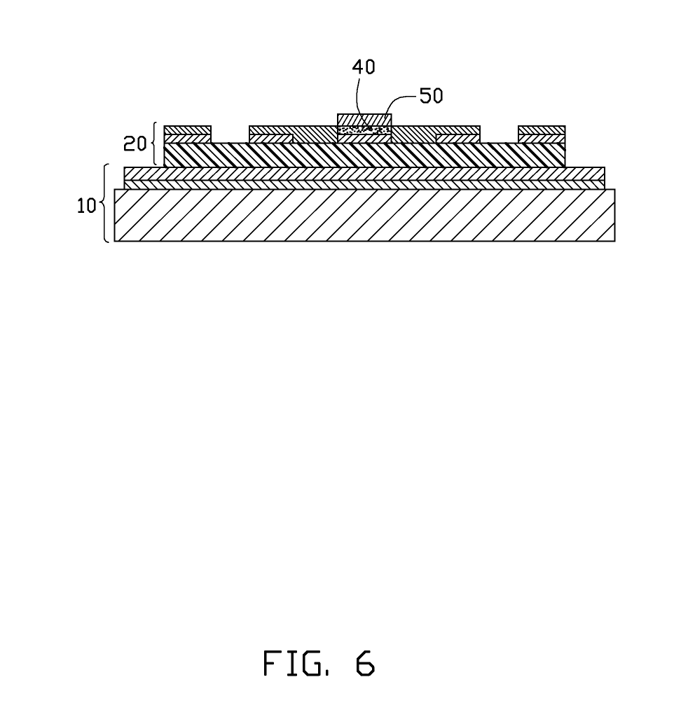

In step 7, as shown in FIG. 6, an electronic components 50 is mounted on the tin cream layer 40 on each of the connecting terminals 28 by a surface mount machine (not shown).

In step 8, the tin cream layer 40 on each of the connecting terminals 28 is heated to melt, then is cooled to solidify, to adhere the electronic component 50 on the tin cream layer 40 firmly. In this embodiment, the heating and cooling process is executed in a reflow oven (not shown).

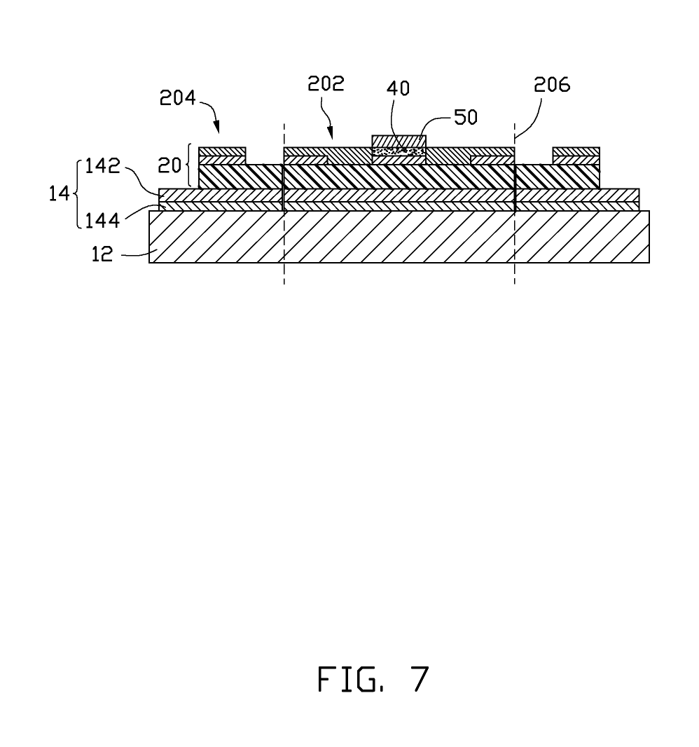

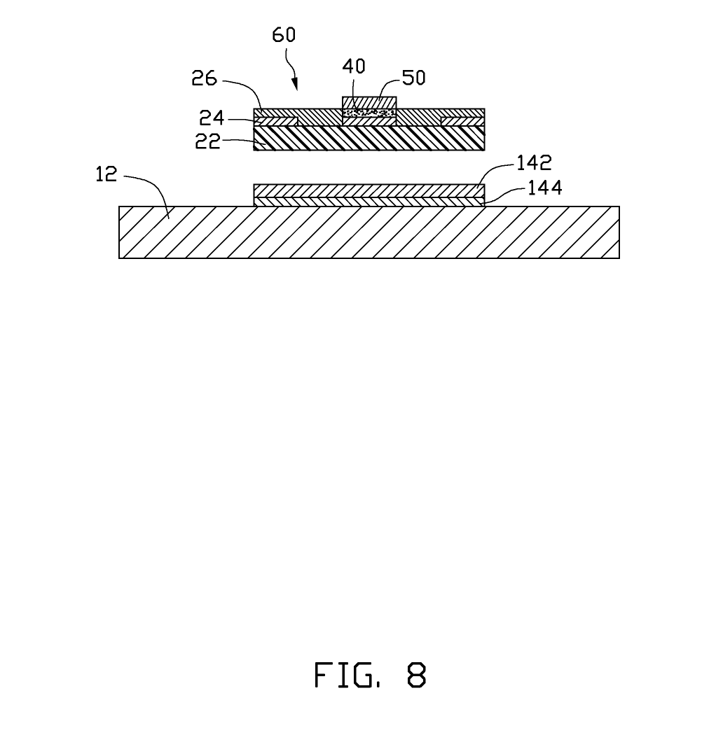

In step 9, as shown in FIGS. 7 and 8, the unfinished FPCB 20 and the connecting plate 14 are cut along the boundary 206 to separate the effective region 202 from the unwanted region 204.

As the unfinished FPCB 20 is separated from the connecting plate 14 at the effective region 202, it is easy to take off the effective region 202 of the unfinished FPCB 20 from the connecting plate 14. In this way, a FPCB 60 is obtained.

As the unfinished FPCB 20 is adhered to the connecting plate 14 and the connecting plate 14 is adhered to the support plate 12, the unfinished FPCB 20 will not wrap during the manufacturing process. In this way, the quality of the FPCB 60 is improved.

It is to be understood, however, that even though numerous characteristics and advantages of the present embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A method for manufacturing a FPCB, the method comprising:
providing a support device, the support device comprising a support plate, an attachment layer positioned on the support plate, and a connecting layer positioned on the attachment layer;
providing an unfinished FPCB, the unfinished FPCB comprising a substrate, a conductive trace layer formed on the substrate, and a solder mask layer formed on the conductive trace layer, the conductive trace layer comprising connecting terminals, the solder mask layer defining holes for exposing the connecting terminals, the unfinished FPCB being divided into an effective region and an unwanted region surrounding the effective region, the connecting terminals located in the effective region;
forming a blinded groove in the unwanted region, the blinded groove extending through the solder mask layer and the conductive trace layer and terminating at the substrate;
putting the unfinished FPCB on the support device, with the substrate in contact with the connecting layer;
inserting a heating device into the blinded groove, the substrate and the connecting layer at the blinded groove being heated by the heating device to adhere to each other;
removing the heating device from the blinded groove;
dispensing a tin cream layer on each of the connecting terminals;
mounting an electronic component on the tin cream layer on each of the connecting terminals; and
cutting the unfinished FPCB to separate the effective region from the unwanted region.

2. The method of claim 1, wherein the support plate is made of aluminum.

3. The method of claim 1, wherein the connecting layer is made of resin.

4. The method of claim 1, wherein the attachment layer is made of resin.

5. The method of claim 1, wherein the attachment layer is a double-sided adhesive.

6. The method of claim 1, wherein the substrate is made of resin.

7. The method of claim 1, wherein the heating device comprises a plurality of heating rods.

8. The method of claim 1, further comprising a step of cooling the substrate and the connecting layer after the step of removing the heating device from the blinded groove.

9. The method of claim 1, wherein a temperature of the heating device is about 300 degrees Celsius.

10. The method of claim 1, wherein a time for which the substrate and the connecting layer at the blinded groove are heated by the heating device is about 0.5 second.
